(19) United States
(12) Patent Application Publication
(10) Pub. No.: US 2017/0045554 A1
(43) Pub. Date: Feb. 16, 2017

(54) CIRCUIT PROBING SYSTEM AND ITS CIRCUIT PROBING DEVICE

(71) Applicants: GLOBAL UNICHIP CORPORATION, HSINCHU CITY (TW); TAIWAN SEMICONDUCTOR MANUFACTURING CO., LTD., HSINCHU (TW)

(72) Inventors: Chih-Chieh LIAO, Taipei City (TW); Yu-Min SUN, New Taipei City (TW); Chih-Feng CHENG, Taoyuan City (TW)

(21) Appl. No.: 14/934,109

(22) Filed: Nov. 5, 2015

(30) Foreign Application Priority Data
Aug. 10, 2015 (TW) 104125997

(51) Int. Cl. G01R 1/16; G01R 1/04

(52) U.S. Cl. CPC G01R 1/16; G01R 1/0408

(57) ABSTRACT

A circuit probing system and a circuit probing device thereof are provided. The circuit probing device includes a probe card and a protective lid. The probe card is provided with a pin area, a bore hole and a first magnetic attraction member disposed in the bore hole. The protective lid is provided with a second magnetic attraction member. When the protective lid covers the probe pin area, and the second magnetic attraction member inserts into the bore hole, the protective lid is fixed on the probe card as the first magnetic attraction member and the second magnetic attraction member magnetically attract with each other.

### RELATED APPLICATIONS

This application claims priority to Taiwan Application Serial Number 104125997, filed Aug. 10, 2015, which is herein incorporated by reference.

### BACKGROUND

Field of Disclosure

The present disclosure relates to a circuit probing system and its circuit probing device. More particularly, the present disclosure relates to a circuit probing system and its circuit probing device for covering a probe pin area.

Description of Related Art

A conventional manufacturing process of semiconductor or an optoelectronic product (e.g., light-emitting diode, liquid crystal display, or plasma display panel) normally includes a quality testing procedure therein. The quality testing procedure measures connection reliabilities and conducting performances of tested circuits thereof by electrically connecting pads of the tested circuits with probe pins of a probe card so that parameters leading circuit defects can be quickly interpreted or amended so as to enhance the process yield.

However, when an operator manually moves the probe card, the operator may inadvertently touch or damage the probe pins of the probe card so that electrical performance and testing results of the probe card can be deteriorated.

Therefore, ways in which to provide a solution to effectively solve the aforementioned inconvenience and shortages and to increase the competitiveness of industries will be seriously concerned.

### SUMMARY

An aspect of the disclosure is to provide a circuit probing system and its circuit probing device to overcome the defects and inconvenience of the prior art.

According to one embodiment, the circuit probing device includes a probe card and a protective lid. The probe card is provided with a pin area, at least one bore hole and at least one first magnetic attraction member disposed in the bore hole. The protective lid is provided with at least one second magnetic attraction member. When the protective lid covers the probe pin area, and the second magnetic attraction member inserts into the bore hole, the protective lid is fixed on the probe card as the first magnetic attraction member and the second magnetic attraction member magnetically attract with each other.

Therefore by the circuit probing device of the embodiment, the possibility that the pin area of the probe card is damaged will be lowered, so that electrical performances and testing results of the probe card cannot be affected.

Based upon the foregoing embodiment, in one specific optional embodiment, the second magnetic attraction member is in a cylindrical shape, and directly connected to one surface of the protective lid.

Based upon the foregoing embodiment, in one specific optional embodiment, the second magnetic attraction member includes a cylindrical body and a magnetic block disposed on one distal end of the cylindrical body.

Base upon the foregoing embodiment, in one specific optional embodiment, the first magnetic attraction member and the second magnetic attraction member are a metal and a magnet; or the first magnetic attraction member and the second magnetic attraction member are magnets.

Based upon the foregoing embodiment, in one specific optional embodiment, the bore hole is provided with a cylindrical passage having a longitudinal direction. The second magnetic attraction member enters the cylindrical passage in the longitudinal direction.

Based upon the foregoing embodiment, in one specific optional embodiment, the bore hole is provided with a cylindrical passage and an opening peripheral edge. The opening peripheral edge connects to the cylindrical passage and surrounds the cylindrical passage. The opening peripheral edge includes a guiding slope surface for guiding the second magnetic attraction member to enter the cylindrical passage.

Based upon the foregoing embodiment, in one specific optional embodiment, the probe card further includes at least one fluorescent layer, the fluorescent layer is connected to the bore hole, and the fluorescent layer is provided with a fluorescent color.

Based upon the foregoing embodiment, in one specific optional embodiment, the protective lid further includes at least one fluorescent layer, the fluorescent layer is disposed on the second magnetic attraction member, and the fluorescent layer is provided with a fluorescent color.

Based upon the foregoing embodiment, in one specific optional embodiment, the protective lid includes an arc surface and a confronting surface, a peripheral edge of the arc surface is connected to a peripheral edge of the confronting surface, and the second magnetic attraction member is disposed on the confronting surface of the protective lid. When the protective lid covers the probe pin area of the probe card, the confronting surface is in contact with the probe card.

Based upon the foregoing embodiment, in one specific optional embodiment, the protective lid further includes a grip portion, the grip portion is arranged on one surface of the protective lid opposite to the second magnetic attraction member, and is used for removing the protective lid away from the probe card.

According to another embodiment, a circuit probing system includes a circuit probing device, an object-removing device and a transmission device. The circuit probing device includes a probe card. The probe card is provided with a probe pin area, at least one bore hole and at least one first magnetic attraction member. The first magnetic attraction member is disposed in the bore hole. The protective lid is provided with at least one second magnetic attraction member and a grip portion. The second magnetic attraction member enters the bore hole in a first direction, and the second magnetic attraction member and the first magnetic attraction member magnetically attract with each other such that the protective lid is fixed on the probe card. The object-removing device removes the protective lid away from the probe card in a second direction opposite to the first direction by moving the grip portion. The transmission device is electrically connected to the object-removing device for driving the object-removing device to move.

Therefore, since the protective lid is removed away from the probe card by an automated mechanism of the circuit probing system of the embodiment, the possibility that an operator manually removes the protective lid away from the probe card can be lowered, or even omitted. Thus, not only does the possibility that the operator inadvertently touches the probe pins of the probe card can be lowered, but also a step of removing the protective lid away from the probe card can be integrated into an entire quality testing procedure so as to enhance the entire quality testing procedure.

Base upon the foregoing embodiment, in one specific optional embodiment, the grip portion includes a neck and a grip head connected to the neck, and a transverse cross-sectional area of the neck is smaller than a transverse cross-sectional area of the grip head.

Base upon the foregoing embodiment, in one specific optional embodiment, the object-removing device includes an object-removing module having a main body and a U-shaped fork. The U-shaped fork is connected to the main body for reaching the neck and abutting the grip head.

Base upon the foregoing embodiment, in one specific optional embodiment, the object-removing device further includes a suction head. The suction head is elevatably connected to the main body so that a changeable gap is formed between the suction head and the U-shaped fork. Thus, when the object-removing device moves the grip head, the suction head and the U-shaped fork in the changeable gap clamp the grip head, and the suction head sucks one surface of the grip head opposite to the neck.

Base upon the foregoing embodiment, in one specific optional embodiment, the object-removing device further includes a vertical guiding module and a horizontal guiding module. The object-removing module is elevatably connected to the vertical guiding module, and the horizontal guiding module is horizontally connected to the vertical guiding module.

It is to be understood that both the foregoing general description and the following detailed description are by examples, and are intended to provide further explanation of the disclosure as claimed.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure. In the drawings,

FIG. 1 is a disassembled view of a probe card and a protective lid of a circuit probing device according to a first embodiment of the disclosure;

FIG. 2 is a top view of the probe card of FIG. 1;

FIG. 3 is a cross sectional view of the probe card taken along line A-A of FIG. 2;

FIG. 4 is a schematic view of the second magnetic attraction member of the protective lid according to a second embodiment of the disclosure;

FIG. 5A-FIG. 5B are operational schematic views of a circuit probing system according to a third embodiment of the disclosure; and

FIG. 6A-FIG. 6B are operational schematic views of a circuit probing system according to a fourth embodiment of the disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts. According to the embodiments, it will be apparent to those skilled in the art that various modifications and variations can be made to the structure of the present disclosure without departing from the scope or spirit of the disclosure.

### First Embodiment

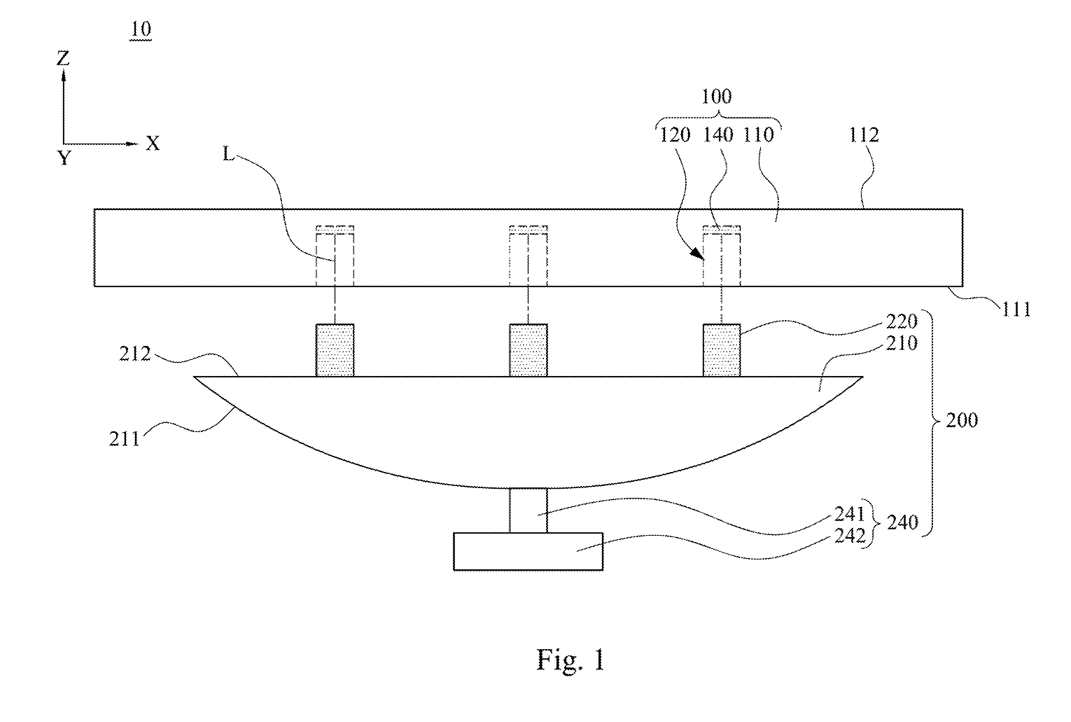

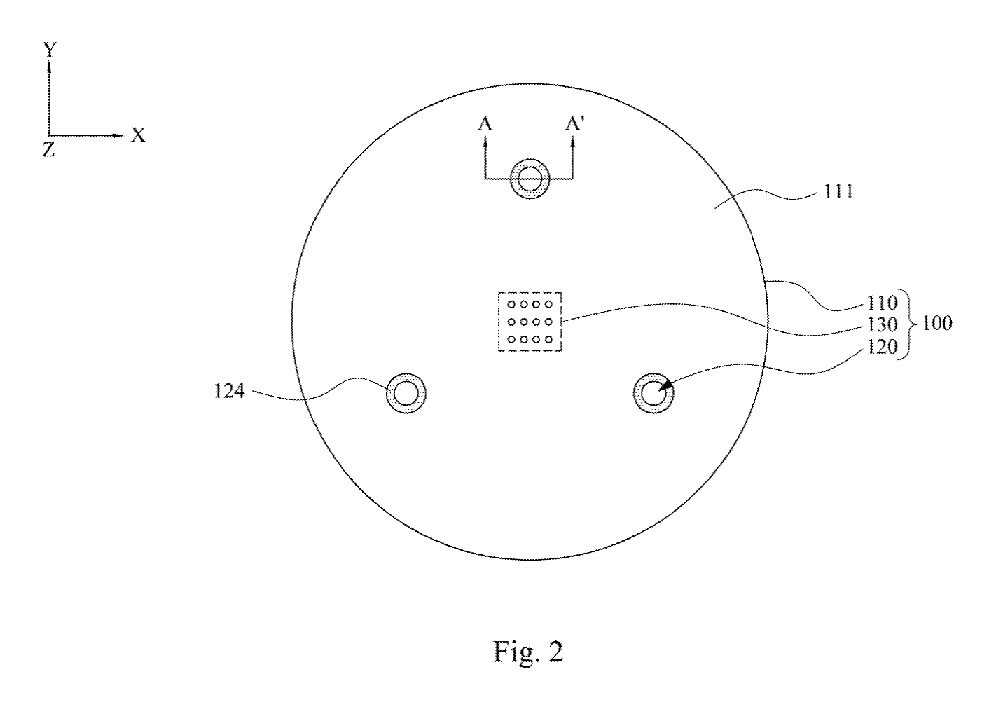

Reference is now made to FIG. 1 and FIG. 2 in which FIG. 1 is a disassembled view of a probe card 100 and a protective lid 200 of a circuit probing device 10 according to a first embodiment of the disclosure. FIG. 2 is a top view of the probe card 100 of FIG. 1. As shown in FIG. 1 and FIG. 2, the circuit probing device 10 includes a probe card 100 and a protective lid 200. The probe card 100 includes a substrate 110, a pin area 130 and a plurality of first magnetic attraction members 140. The substrate 110 is provided with a front surface 111 and a rear surface 112 opposite to the front surface 111. The pin area 130 is disposed on the front surface 111 of the substrate 110. A plurality of bore holes 120 are respectively formed on the front surface 111 of the substrate 110. Each of the first magnetic attraction members 140 is installed in one of the bore holes 120, and is coupled to the substrate 110. The protective lid 200 is removably fixed to the probe card 100. The protective lid 200 includes a cover 210 and a plurality of second magnetic attraction members 220. The second magnetic attraction members 220 are respectively distributed on the cover 210.

When the protective lid 200 covers the front surface 111 of the substrate 110 so as to cover the probe pin area 130 thereon, since the second magnetic attraction members 220 respectively insert into the bore holes 120, and the first magnetic attraction member 140 and the second magnetic attraction member 220 are magnetically attracted with each other, thus, the protective lid 200 is fixed on the probe card 100. Therefore, as the protective lid 200 fixedly covers the pin area 130, by the circuit probing device 10 of the embodiment, the possibility that the probe card 100 is damaged will be lowered, so that electrical performances and testing results of the probe card 100 cannot be effected.

In great details, the cover 210 is in a hemispherical shape, and the cover 210 includes an arc surface 211 and a confronting surface 212. A peripheral edge of the confronting surface 212 is connected to a peripheral edge of the arc surface 211, and the second magnetic attraction members 220 are respectively disposed on the confronting surface 212 of the protective lid 200. Thus, when the protective lid 200 is assembled to the probe card 100, and the confronting surface 212 of the protective lid 200 is substantially in contact with the front surface 111 of the substrate 110, if the protective lid 200 is impacted by a foreign object, because the arc surface 211 of the protective lid 200 is with a predetermined curve degrees, the arc surface 211 can effectively divert the impact of the foreign object away so as to lower the possibility of damage to the protective lid 200 and the probe card 100. The cover 210 is not limited to be a metal cover or a transparent plastic cover. The cover is not limited to shapes and materials in the disclosure.

Furthermore, when the protective lid 200 covers the front surface 111 of the substrate 110 since the second magnetic attraction members 220 are arranged to present as a regular polygon shape (e.g., a triangular shape) on the confronting surface 212 of the protective lid 200, the securing strength of the protective lid 200 fixing on the probe card 100 can be more balanced. It is noted that as long as pins in the pin area 130 can be avoided from being damaged, the protective lid 200 in the embodiment is not limited to be either a solid or hollow protective lid.

In this embodiment, each of the first magnetic attraction members 140, for example, can be a metal sheet or a magnet (e.g., permanent magnet), and each of the first magnetic attraction members 140 is flat disposed in the bottom of each of the bore holes 120. Each of the second magnetic attraction members 220 is in a cylindrical shape, and each of the second magnetic attraction members 220 is directly connected to the cover 210, and is used for fully inserting into the corresponding bore hole 120 to magnetically attract wit the corresponding first magnetic attraction member 140. For example, each of the second magnetic attraction members 220 can be made of a magnet (e.g., permanent magnet) completely; however, the second magnetic attraction member is not limited to being the permanent magnet only in the disclosure.

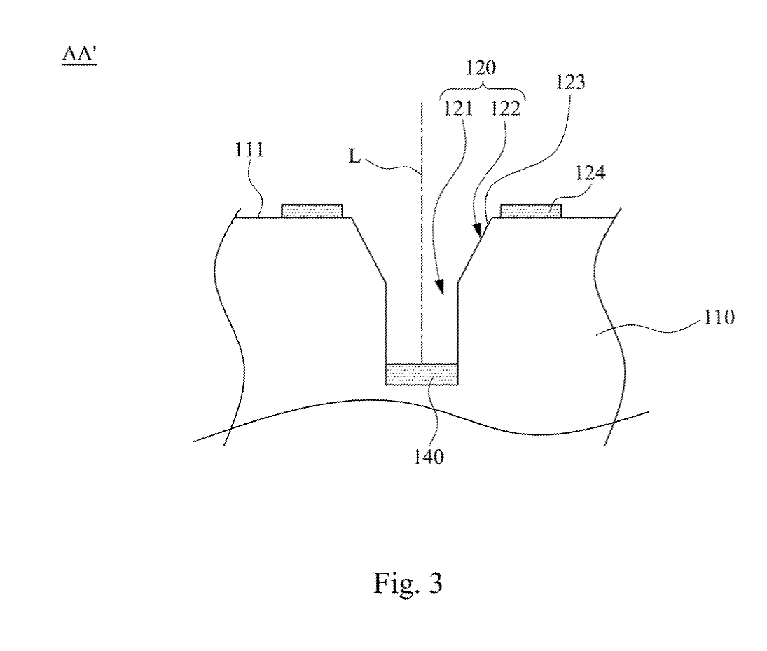

FIG. 3 is a cross sectional view of the probe card taken along line A-A of FIG. 2. As shown in FIG. 1 and FIG. 3, each of the bore holes 120 is provided with a cylindrical passage 121 and an opening peripheral edge 122. The opening peripheral edge 122 connects to the cylindrical passage 121 and the front surface 111 of the substrate 110, and the opening peripheral edge 122 surrounds the cylindrical passage 121. The cylindrical passage is provided with a longitudinal direction L. Thus, when the protective lid 200 is assembled on the probe card 100 by the operator, the second magnetic attraction members 200 are required to linearly insert into the cylindrical passages 121 along the longitudinal direction L towards a first direction (i.e., Z axis upward) so as to avoid from damage to the pin area 130 because of inadvertently sliding of the protective lid 200. Also, after the protective lid 200 is assembled on the probe card 100, since each of the cylindrical passage 121 of the bore holes 120 has a predetermined length so that each of the second magnetic attraction members 200 in the corresponding bore hole 120 will not be easily removed from the corresponding bore hole 120. The opening peripheral edge 122 includes a guiding slope surface 123. The guiding slope surface 123 inclinedly connects to the cylindrical passage 121 and the front surface 111 of the substrate 110 so as to guide the second magnetic attraction member 200 to enter the cylindrical passage 121. However, the disclosure is not limited thereto.

Moreover, a transverse cross-sectional area of each of the second magnetic attraction members 220 is substantially set to match a bore diameter of the corresponding bore hole 120. Thus, after the second magnetic attraction members 220 are respectively inserted into the bore holes 120, the second magnetic attraction members 220 are able to be tightly fit in the bore holes 120 so that the securing strength of the protective lid 200 fixing on the probe card 100 can be more enhanced. However, in the disclosure, a transverse cross-sectional area of each of the second magnetic attraction members does not have to match a bore diameter of the corresponding bore hole.

Also, in order to quickly align with the corresponding the bore holes 120 by each of the second magnetic attraction members 220, in this embodiment, the front surface 111 of the substrate 110 further includes a plurality of fluorescent layers 124. Each of the fluorescent layers 124 is connected to one of the bore holes 120. For example, each of the fluorescent layers 124 is applied on the opening peripheral edge 122 of the bore hole 120, or each of the fluorescent layers is applied on the front surface adjacent to the opening peripheral edge of the bore hole. Therefore, since each of the fluorescent layers 124 is provided with a fluorescent color, and the fluorescent color is apparently different to the natural color of the front surface 111 of the probe card 100, the operator can be effectively assisted for quickly identifying the location of the bore holes 120 so as to shorten the operation time of the protective lid assembled on the probe card. However, in the disclosure, each of the fluorescent layers is not limited to be applied on the opening peripheral edge of the bore hole of the probe card only, in another embodiment, another fluorescent layer (not shown in figures) also can be disposed on each of the second magnetic attraction members of the protective lid.

In addition, the protective lid 200 further includes a grip portion 240. The grip portion 240 is arranged on the arc surface 211 of the protective lid 200 opposite to the second magnetic attraction members 220. Thus, the protective lid 200 can be linearly removed away from the probe card 100 along the longitudinal direction L towards a second direction (i.e., Z axis downward) by moving the grip portion 240 by the operator. Specifically, the grip portion 240 includes a neck 241 and a grip head 242. The neck 241 is arranged between the arc surface 211 of the cover 210 and the grip head 242, and connected to the arc surface 211 of the cover 210 and the grip head 242. A transverse cross-sectional area of the neck 241 is smaller than a transverse cross-sectional area of the grip head 242, that is, the neck 241 is narrower than the grip head 242.

### Second Embodiment

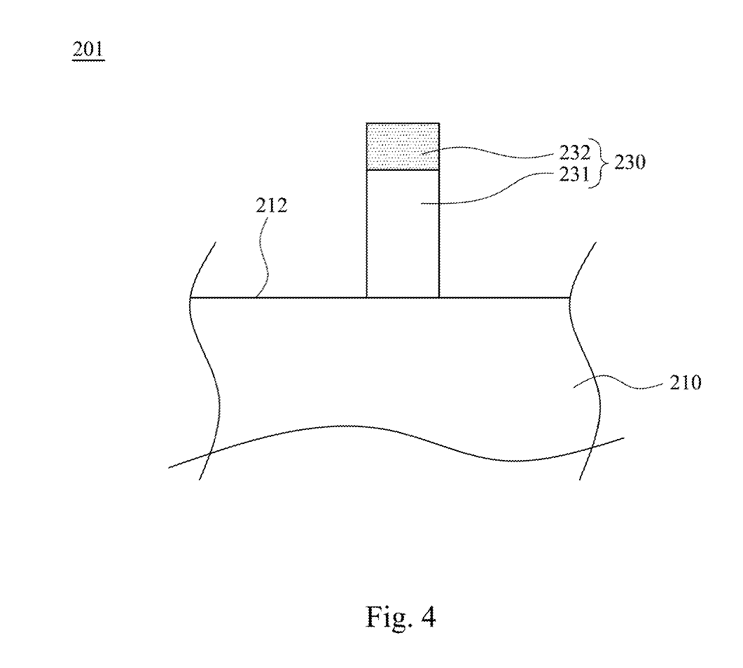

The circuit probing device of the second embodiment is substantially the same to the circuit probing device of the first embodiment, except that each of the second magnetic attraction members 220 in the first embodiment (FIG. 1) is made of a magnet (e.g., permanent magnet) completely. In contrast, FIG. 4 is a schematic view of the second magnetic attraction member 230 of the protective lid 201 according to the second embodiment of the disclosure. As shown in FIG. 4, each of the second magnetic attraction members 230 includes a cylindrical body 231 and a magnetic block 232 disposed on one distal end of the cylindrical body 231. The cylindrical body 231 is disposed between the magnetic block 232 and the cover 210 so that the magnetic block 232 can be magnetically attracted with one of the first magnetic attraction members 140.

Thus, comparing to each of the second magnetic attraction members 220 shown in FIG. 1 made of the magnet (e.g., permanent magnet) completely, a smaller size of the magnetic block 232 of the second embodiment disposed on one distal end of the cylindrical body 231 can be magnetically attracted with one of the first magnetic attraction members 140 so that not only does the desired magnetic force of the second magnetic attraction member 220 can be adjusted, but also the purchase cost of the magnet can be decreased.

### Third Embodiment

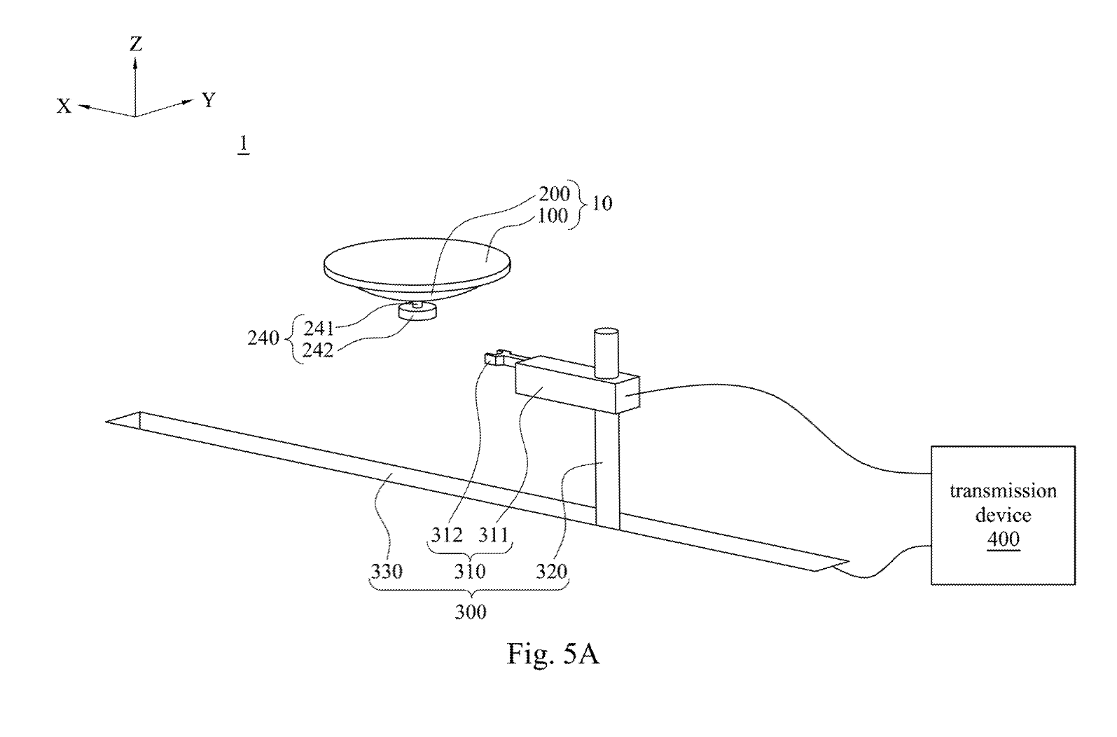

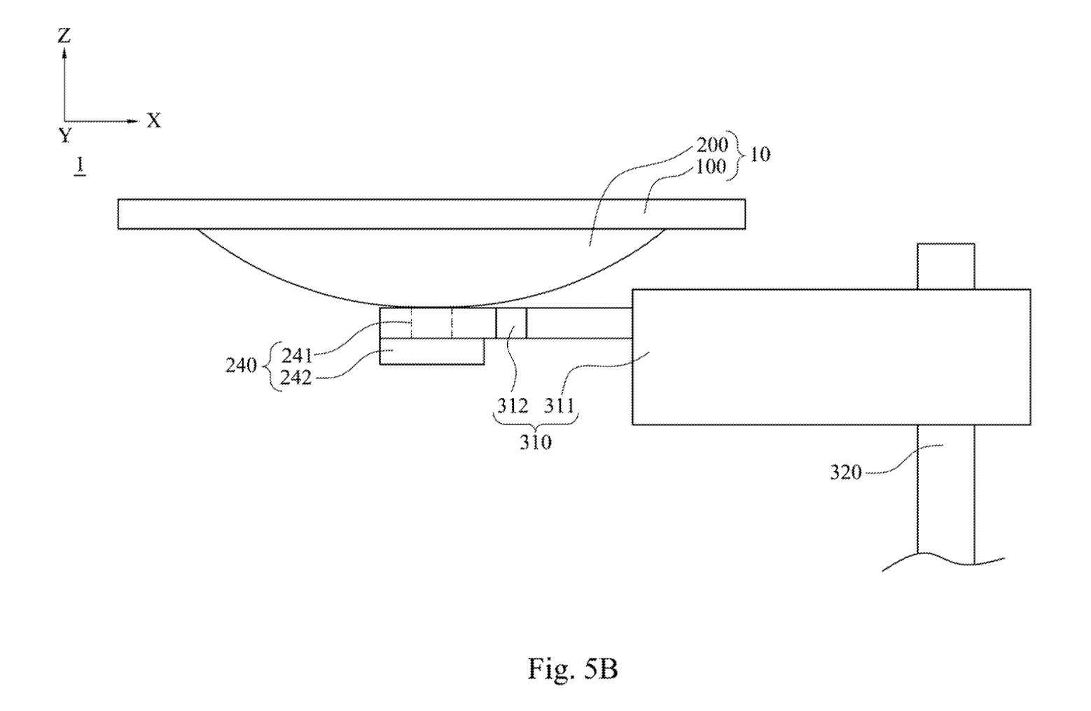

FIG. 5A-FIG. 5B are operational schematic views of a circuit probing system 1 according to a third embodiment of the disclosure. As shown in FIG. 5A-FIG. 5B, in this embodiment, the circuit probing system 1 includes the aforementioned circuit probing device 10, an object-removing device 300 and a transmission device 400. All features of the circuit probing device 10 of the aforementioned embodiments can be adapted to the circuit probing device 10 of the third embodiment. The object-removing device 300 linearly removes the protective lid 200 away from the probe card 100 in a second direction (i.e., Z axis downward) by moving the grip portion 240. The transmission device 400 is electrically connected to the object-removing device 300 for driving the object-removing device 300 to move. The transmission device 400, for example, can be a motor, a cylinder or other conventional techniques, however, the disclosure is not limited thereto, one skilled in the art of the disclosure may be flexible to select the appropriate type of the transmission device according to the actual requirements.

Therefore, since the protective lid is removed away by an automated mechanism, the possibility that the protective lid is manually removed away can be lowered, or even omitted by the circuit probing system of the embodiment. Thus, not only does the possibility that the operator inadvertently touches the probe pins of the probe card be reduced, but also a step of removing the protective lid away from the probe card can be integrated into an entire quality testing procedure so as to well smooth the entire quality testing procedure.

In the third embodiment, the object-removing device includes an object-removing module 310, a vertical guiding module 320 and a horizontal guiding module 330. The object-removing module 310 is elevatably connected to the vertical guiding module 320, and the vertical guiding module 320 is horizontally connected to the horizontal guiding module 330. The object-removing module 310 includes a main body 311 and a U-shaped fork 312. The U-shaped fork 312 is connected to one side of the main body 311.

Therefore, when the protective lid 200 is being removed, the object-removing module 310 can be carried to reach the grip head 242 and abut the grip head 242 with the operation of the vertical guiding module 320 and the horizontal guiding module 330 in turns (FIG. 5B). For example, the U-shaped fork 312 receives the neck 241 therein, and the U-shaped fork 312 abuts the grip head 242. Finally, the object-removing module 310 is moved in the second direction (i.e., Z axis downward) by the vertical guiding module 320 so that the protective lid 200 can be linearly removed away from the probe card 100. Thus, the probe card 100 can continue the subsequent testing steps of the quality testing procedure.

Since a pulling force of the object-removing module 310 being moved downwardly is greater than an attraction force of the magnetic attraction members which are magnetically attracted with each other, the protective lid 200 can be moved downwardly away from the probe card 100. Furthermore, since the neck 241 is narrower than the grip head 242, the U-shaped fork 312 presses one surface of the grip head 242 connecting to the neck 241 as an application point to achieve the remove of the protective lid 200. However, the disclosure is not limited thereto. As long as the protective lid can be stably removed from the probe card, the grip head is not limited in the aforementioned structures in the disclosure, and one skilled in the art of the disclosure may be flexible to select the appropriate type of the grip head according to the actual requirements.

It is noted, as long as the vertical guiding module and the horizontal guiding module can stably move the object-removing module for removing the protective lid, the vertical guiding module and the horizontal guiding module are not only limited to be ball screw modules, guiding rail modules, motor transportation conveyors or other conventional techniques. Also, the object-removing device is not only limited to move in an axial direction in the disclosure, in another embodiment, the object-removing device also can be carried by a mechanical robot arm capable of moving in three-dimensional motion. One skilled in the art of the disclosure may be flexible to select the appropriate type of the object-removing device according to the actual requirements.

### Fourth Embodiment

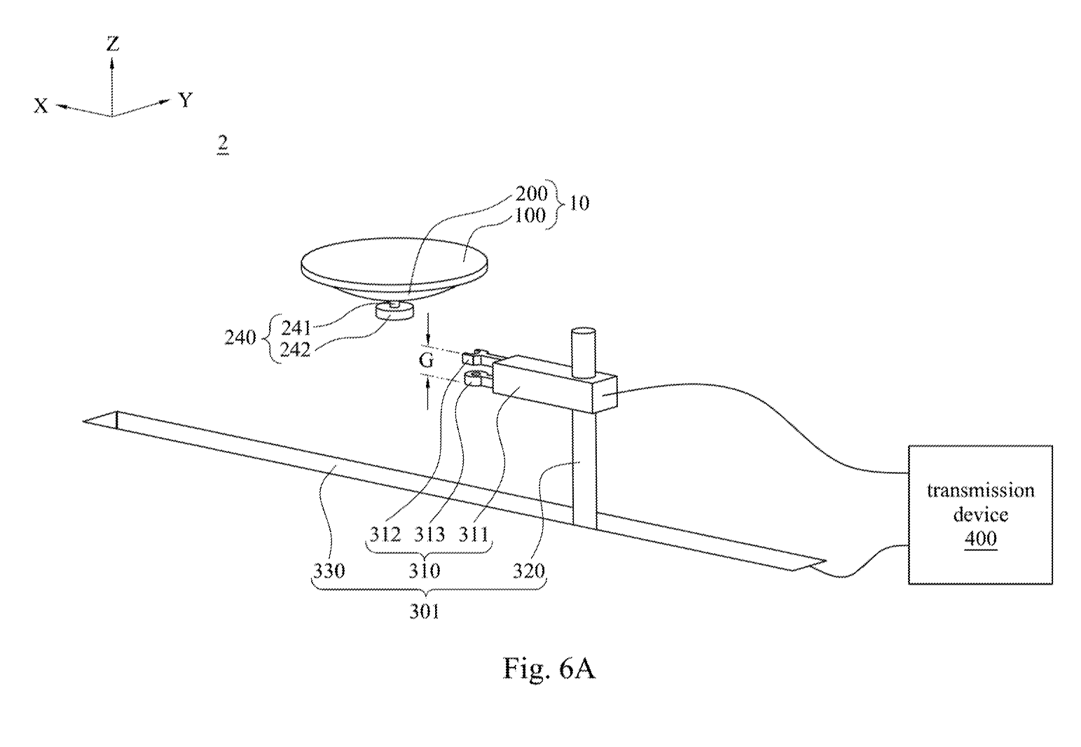

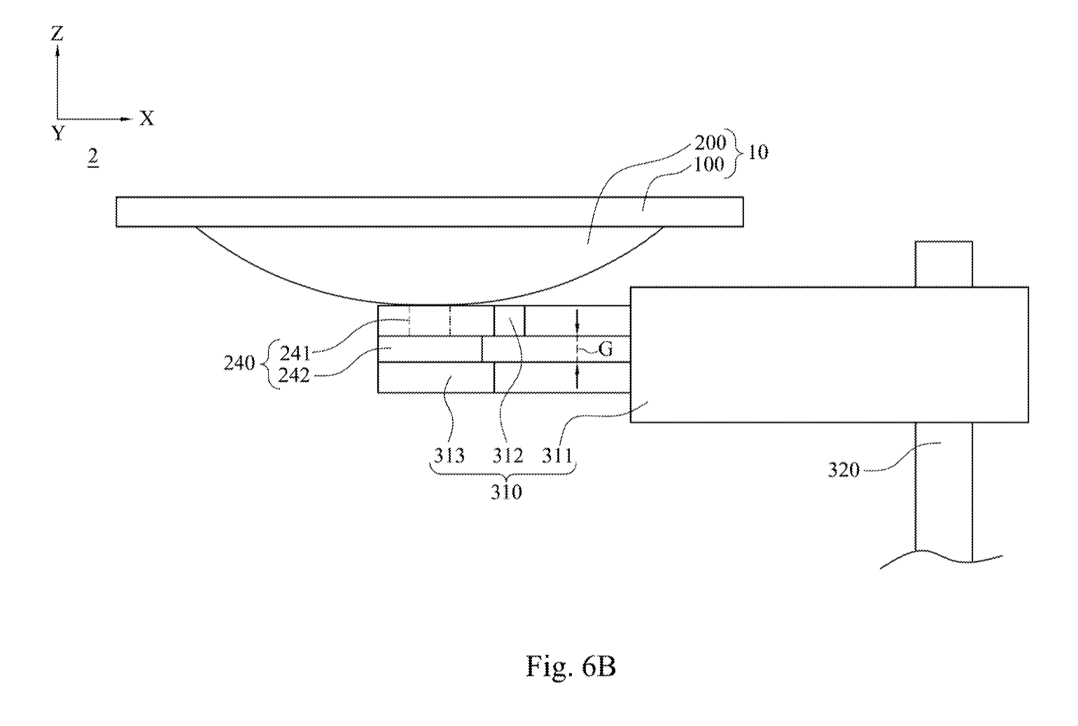

FIG. 6A-FIG. 6B are operational schematic views of a circuit probing system 2 according to a fourth embodiment of the disclosure. The circuit probing system 2 of the fourth embodiment is substantially the same to the circuit probing system 1 of the third embodiment, as shown in FIG. 6A-FIG. 6B, except that the object-removing module 310 of the object-removing device 301 further includes a suction head 313. The suction head 313 and the U-shaped fork 312 are respectively connected to the same side of the main body 311. The suction head 313 is elevatably connected to the main body 311 so that a changeable gap G is formed between the suction head 313 and the U-shaped fork 312.

Thus, as shown in FIG. 6, in the process of the remove of the protective lid 200, when the U-shaped fork 312 is moved to the neck 241 of the grip portion 240, the suction head 313 then moves to another surface of the grip head 242 opposite to the neck 241, thus, the grip head 242 is clamped by the suction head 313 and the U-shaped fork 312 in the changeable gap G, that is, the changeable gap G at this moment is equal to the thickness of the grip head 242.

In the fourth embodiment, besides the grip head 242 is clamped by the suction head 313 and the U-shaped fork 312, the suction head 313 further provides suction force for sucking one surface of the grip head 242 opposite to the neck 241. Thus, when the object-removing module 310 is linearly moved downwardly, since the grip portion 240 is stably clamped by the object-removing module 310, the shake level of the object-removing device 301 linearly moved downwards from the probe card 100 can be reduced.

Also, since the suction head 313 can dynamically moved to adjust the changeable gap G in accordance with the size of the grip head 242, the issue that another grip portion having different size cannot be held can be overcome.

In the aforementioned embodiment, the suction head is not only limited to vacuum suctions or rubber suction disks. One skilled in the art of the disclosure may be flexible to select the appropriate type of the suction head according to the actual requirements.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A circuit probing device comprising:
a probe card having a probe pin area, at least one bore hole, and at least one first magnetic attraction member is disposed in the bore hole;
a protective lid having at least one second magnetic attraction member,
wherein, when the protective lid covers the probe pin area of the probe card, and the second magnetic attraction member inserts into the bore hole of the probe card, the protective lid is fixed on the probe card as the first magnetic attraction member and the second magnetic attraction member magnetically attract with each other.

2. The circuit probing device of claim 1, wherein the second magnetic attraction member comprises a cylindrical body and a magnetic block disposed on one distal end of the cylindrical body.

3. The circuit probing device of claim 1, wherein the second magnetic attraction member is in a cylindrical shape, and directly connected to one surface of the protective lid.

4. The circuit probing device of claim 1, wherein the first magnetic attraction member and the second magnetic attraction member are a metal and a magnet; or the first magnetic attraction member and the second magnetic attraction member are magnets.

5. The circuit probing device of claim 1, wherein the bore hole is provided with a cylindrical passage having a longitudinal direction, wherein the second magnetic attraction member enters the cylindrical passage in the longitudinal direction.

6. The circuit probing device of claim 1, wherein the bore hole is provided with a cylindrical passage and an opening peripheral edge, the opening peripheral edge connects to the cylindrical passage and surrounds the cylindrical passage, wherein the opening peripheral edge includes a guiding slope surface for guiding the second magnetic attraction member to enter the cylindrical passage.

7. The circuit probing device of claim 1, wherein the probe card further comprises at least one fluorescent layer, the fluorescent layer is connected to the bore hole, wherein the fluorescent layer is provided with a fluorescent color.

8. The circuit probing device of claim 1, wherein the protective lid further comprises at least one fluorescent layer, the fluorescent layer is disposed on the second magnetic attraction member, wherein the fluorescent layer is provided with a fluorescent color.

9. The circuit probing device of claim 1, wherein the protective lid comprises an arc surface and a confronting surface, a peripheral edge of the arc surface is connected to a peripheral edge of the confronting surface, and the second magnetic attraction member is disposed on the confronting surface of the protective lid, wherein, when the protective lid covers the probe pin area of the probe card, the confronting surface is in contact with the probe card.

10. The circuit probing device of claim 1, wherein the protective lid further comprises a grip portion, the grip portion is arranged on one surface of the protective lid opposite to the second magnetic attraction member, and used for removing the protective lid away from the probe card.

11. A circuit probing system comprising:
a circuit probing device comprising:
a probe card having a probe pin area, at least one bore hole and at least one first magnetic attraction member disposed in the bore hole; and
a protective lid having at least one second magnetic attraction member and a grip portion, the second magnetic attraction member enters the bore hole in a first direction, and the second magnetic attraction member and the first magnetic attraction member magnetically attract with each other such that the protective lid is fixed on the probe card;
an object-removing device for removing the protective lid away from the probe card in a second direction by moving the grip portion, wherein the second direction is opposite to the first direction; and
a transmission device electrically connected to the object-removing device for driving the object-removing device to move.

12. The circuit probing system of claim 11, wherein the grip portion comprises a neck and a grip head connected to the neck, and a transverse cross-sectional area of the neck is smaller than a transverse cross-sectional area of the grip head.

13. The circuit probing system of claim 12, wherein the object-removing device comprises an object-removing module having a main body and a U-shaped fork, the U-shaped fork is connected to the main body for reaching the neck and abutting the grip head.

14. The circuit probing system of claim 13, wherein the object-removing device further comprises a vertical guiding module and a horizontal guiding module, the object-removing module is elevatably connected to the vertical guiding module, and the horizontal guiding module is horizontally connected to the vertical guiding module.

15. The circuit probing system of claim 13, wherein the object-removing device further comprises a suction head, the suction head is elevatably connected to the main body so that a changeable gap is formed between the suction head and the U-shaped fork, wherein, when the object-removing device moves the grip head, the grip head is clamped by the suction head and the U-shaped fork in the changeable gap, and the suction head sucks one surface of the grip head opposite to the neck.

16. The circuit probing system of claim 15, wherein the object-removing device further comprises a vertical guiding module and a horizontal guiding module, the object-removing module is elevatably connected to the vertical guiding module, and the horizontal guiding module is horizontally connected to the vertical guiding module.

17. The circuit probing system of claim 11, wherein the first magnetic attraction member and the second magnetic attraction member are a metal and a magnet; or the first magnetic attraction member and the second magnetic attraction member are magnets.

18. The circuit probing system of claim 11, wherein the bore hole is provided with a cylindrical passage having a longitudinal direction, wherein the longitudinal direction is the same as the first direction.

19. The circuit probing system of claim 11, wherein the protective lid comprises an arc surface and a confronting surface, a peripheral edge of the arc surface is connected to a peripheral edge of the confronting surface, and the confronting surface is in contact with the probe card, wherein the second magnetic attraction member is disposed on the confronting surface of the protective lid.
